(19) United States
(12) Patent Application Publication
(10) Pub. No.: US 2016/0139182 A1
(43) Pub. Date: May 19, 2016

(54) SINE WAVE ANALYSIS METHOD AND APPARATUS

(71) Applicant: Robert J. Pond, Doylestown, OH (US)

(72) Inventor: Robert J. Pond, Doylestown, OH (US)

(21) Appl. No.: 14/940,547

(22) Filed: Nov. 13, 2015

Related U.S. Application Data
(60) Provisional application No. 62/079,152, filed on Nov. 13, 2014.

(51) Int. Cl. G01R 19/04; G01R 25/00; G01R 23/00

(52) U.S. Cl. CPC G01R 19/04; G01R 23/00; G01R 25/00

(57) ABSTRACT

Provided, is an apparatus and method for sampling or otherwise processing an alternating wave. A sensor senses a value of the alternating wave at a plurality of equally-spaced times during a period of the alternating wave. These equally-spaced times are determined independent of at least one of a frequency and a phase of the alternating wave. A controller determines, independently of the frequency and the phase of the alternating wave, a desired value of the alternating wave pertinent to a predetermined application of the apparatus based on the value of the alternating wave sensed by the sensor.

### CROSS-REFERENCE TO RELATED APPLICATIONS

This application claims the benefit of U.S. Provisional Application No. 62/079,152, filed Nov. 13, 2014, which is incorporated in its entirety herein by reference.

### BACKGROUND OF THE INVENTION

1. Field of the Invention

This application relates generally to a method and apparatus for analyzing the properties of a sinusoidal signal and, more particularly, to devices and methodologies for determining the amplitude, frequency and/or phase angle of a sinusoidal signal independent of the phase and frequency of the sampling clock.

2. Description of Related Art

Alternating signals such as sinusoidal signals, interchangeably referred to herein as “sine waves,” for example, have been a key element in technology for generations. Power generation, broadcasting and sensors are some of the areas made possible by the generation and detection of sine waves in the analog realm. More recently, digital creation and detection of sine waves has become important with the introduction of analog to digital (“A/D”) and D/A converters, for example. The advent of A/D converters ushered in a new age of speed and accuracy along with a new set of problems, namely, performing the A/D sampling precisely at the peak of the sine wave for accuracy. This entailed adding Phase Locked Loop (“PLL”) circuits to ensure that the A/D sampling time tracks the sine wave peak. Alternatively, complex digital filters were required to extract the desired parameters.

The introduction of microcontrollers (μC's), digital signal processors (DSP's) and other such processing circuitry (hereinafter generically referred to as “processors”) having such converters has helped convert previously “analog” products where engineers dealt with component values, tolerances and power ratings to “digital” designs having firmware, algorithms and sampling rates. Although the digital designs offer a greater degree of flexibility than their analog counterparts, utilizing A/D converter components with processors introduces new technical challenges.

### BRIEF SUMMARY OF THE INVENTION

Accordingly, there is a need in the art for an efficient processor and a method of processing a sine wave that makes efficient use of available system resources to improve performance of the processor for its intended application. Such a processor and method consume relatively little memory and facilitate rapid execution of the sine wave processing.

According to one aspect, the subject application involves an apparatus for sampling an alternating wave. The apparatus includes a sensor that senses a value of the alternating wave at a plurality of equally-spaced times during a period of the alternating wave, where these times are determined independent of at least one of, and optionally both of a frequency and a phase of the alternating wave. A controller determines, independently of the one or both of the frequency and the phase of the alternating wave, a desired value of the alternating wave pertinent to a predetermined application of the apparatus based on the value of the alternating wave sensed by the sensor.

According to another aspect, the subject application involves a method of processing an alternating wave. The method includes sampling, with a sensor, a value of the alternating wave at a plurality of equally-spaced times during a period of the alternating wave, where the equally-spaced times are determined independently of at least one of a frequency and a phase of the alternating wave. During an A/D conversion of the alternating signal, and independently of the at least one of the frequency and the phase of the alternating wave, a desired value of the alternating wave pertinent to a predetermined application of the apparatus is determined based on the value of the alternating wave sensed by the sensor at the equally-spaced times.

The above summary presents a simplified summary in order to provide a basic understanding of some aspects of the systems and/or methods discussed herein. This summary is not an extensive overview of the systems and/or methods discussed herein. It is not intended to identify key/critical elements or to delineate the scope of such systems and/or methods. Its sole purpose is to present some concepts in a simplified form as a prelude to the more detailed description that is presented later.

### BRIEF DESCRIPTION OF SEVERAL VIEWS OF THE DRAWING

The invention may take physical form in certain parts and arrangement of parts, embodiments of which will be described in detail in this specification and illustrated in the accompanying drawings which form a part hereof and wherein:

FIG. 1 schematically shows a sine wave signal and various measurement points;

FIG. 2 is a schematic block diagram of an embodiment of a system for determining the amplitude and phase angle of a sine wave;

FIG. 3 is a schematic processing flow diagram;

FIG. 4 is a schematic block diagram for an inductive proximity sensor according to an illustrative embodiment that utilizes free induction decay to sense an approaching metal object;

FIG. 5 shows an illustrative damped sine wave generated by the inductive proximity sensor in FIG. 4;

FIG. 6 shows another illustrative free induction decay sine wave generated by an Earth's magnetic field NMR magnetometer;

FIG. 7 is a plot illustrating a variation of equation (4) as a function of x;

FIG. 8A shows a schematic representation of signal paths and a configuration of the inventive apparatus and method for processing an A/D conversion;

FIG. 8B shows a schematic representation of a conventional method and apparatus for processing an A/D conversion requiring the use of a numerically controlled oscillator or other phase and/or frequency tracking component; and

FIG. 9 shows a plot comparing the results of different approximations used for sampling a sine wave near a peak amplitude.

### DETAILED DESCRIPTION OF THE INVENTION

Certain terminology is used herein for convenience only and is not to be taken as a limitation on the present invention. Relative language used herein is best understood with reference to the drawings, in which like numerals are used to identify like or similar items. Further, in the drawings, certain features may be shown in somewhat schematic form.

It is also to be noted that the phrase “at least one of”, if used herein, followed by a plurality of members herein means one of the members, or a combination of more than one of the members. For example, the phrase “at least one of a first widget and a second widget” means in the present application: the first widget, the second widget, or the first widget and the second widget. Likewise, “at least one of a first widget, a second widget and a third widget” means in the present application: the first widget, the second widget, the third widget, the first widget and the second widget, the first widget and the third widget, the second widget and the third widget, or the first widget and the second widget and the third widget.

The inventive processor and processing method are described herein in the context of determining at least one of the amplitude, decay constant, frequency and phase angle of a sine wave sampled at a uniform, arbitrary rate by an A/D converter, but can be utilized to determine other qualities of the sine wave. Further, the inventive processor and processing method allow for the determination of the amplitude and phase angle of the sine wave via measurements that need not be made at the peak of the sine wave. The inventive processor and method also reduce the effect of sampling frequency jitter because the any deviations of the sine wave from a true periodic signal during sampling will not adversely affect the sampling described herein, which occurs at arbitrary times during the sinusoidal period. Accordingly, the inventive processor and processing method can optionally lack tracking or synchronization circuitry such as a PLL. The decay constant and frequency of the sine wave so determined, for example, can also be applied to a variety of technologies, but are described herein with application to demodulation for the sake of brevity and clarity.

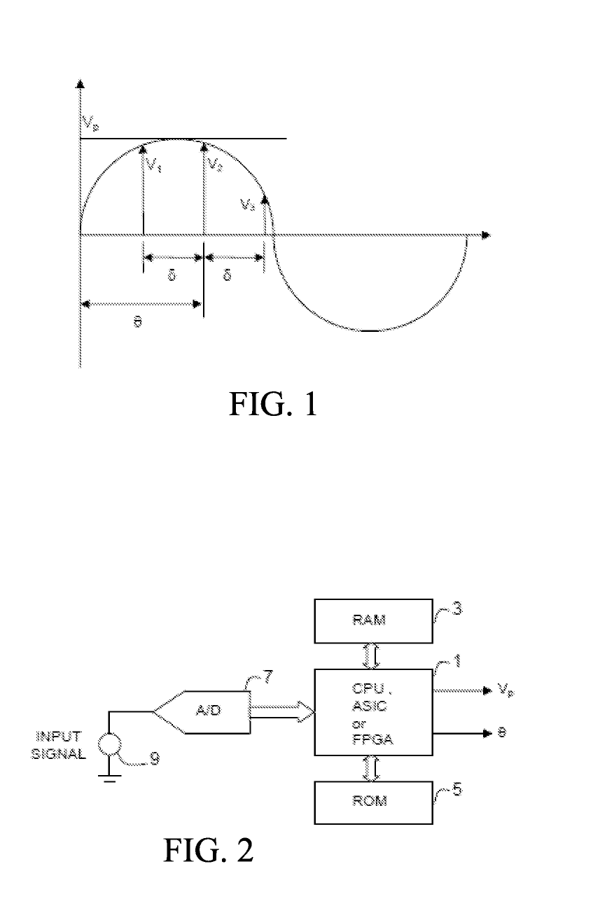

One period of an illustrative sine wave is shown in FIG. 1, and an illustrative embodiment of a system for determining the amplitude, frequency and phase angle of the sine wave is shown in FIG. 2. As shown, the system includes a controller 1, which can include a digital signal processor (DSP), microprocessor, microcontroller, field-programmable gate array (FPGA), application specific integrated circuit (ASIC) or any other type of processor for executing various control operations and calculations discussed below. The controller 1 can include on-board (i.e., located on a common integrated circuit with the controller) memory portions or separate memory portions. Example memory portions include random-access memory (RAM) 3 and/or read-only memory (ROM) 5. Computer-executable instructions executed by the controller 1 in performing the various control operations and calculations can be stored in the ROM 5 and/or RAM 3. Further, parameters used by the controller in executing the program can also be stored in the ROM 5 and/or RAM 3, or other storage registers for storing temporary data. Example parameters include voltage level measurements, angle measurements, decay constant and time measurements and various calculation results. The controller can further include an on-board or separate A/D converter 7 that senses the values of the sine wave and acquires samples of the sine wave provided by an input signal source 9.

In the description that follows, the controller 1 is a microcontroller having an on-board A/D converter 7 with a high sampling bandwidth and on-board RAM 3 and ROM 5. In other words, the controller 1, the A/D converter 7, the RAM 3 and ROM 5 are all integrated into a common package to form an integrated circuit. The A/D converter 7 of the microcontroller is directly connected to an input signal source 9 for determining the amplitude and phase angle of a sine wave provided by the signal source. Passive components (for filtering or noise reduction) or active components (for amplification) may be inserted between the signal source 9 and the A/D converter 7. Examples of commercially available microcontrollers include the model MSP430 family of microcontrollers provided by TEXAS INSTRUMENTS®. Further, the discussion below focuses on the processing of a sine wave during an A/D conversion performed without compensation for any differences between the phase and/or frequency of the sine wave and the sampling clock. Although the detailed description focuses on only the sine wave for purposes of brevity and clarity, it is noted that a cosine wave is another form of a periodic, alternating signal that differs from a sine wave of the same frequency by a phase shift of 90° (π/2 radians). Accordingly, the present disclosure also encompasses similar derivations, algorithms and apparatus compensating for this phase shift to process an A/D conversion of a cosine signal.

The inventive method is a new approach to reducing the data from a sequence of A/D conversions taken from sensors, broadcast or other wireless signals and any other signals. The analysis assumes a series of samples taken with an arbitrary, constant sample rate suitable to take at least a predetermined minimum number of samples in during a period of the sine wave. This approach permits the A/D converter 7 to operate at the maximum possible sample rate without CPU intervention of the microcontroller 1. A side benefit is the averaging in the associated algorithms that increase sensitivity and/or reduce noise. The simple algorithms also can be executed at high speed, thereby decreasing the response time.

With reference to FIG. 1, the amplitude and phase angle of a sine wave can be determined from 3 equally spaced measurements. None of the 3 measurements must be made at the peak of the sine wave. However, it is to be appreciated that one of the measurements can occur at the peak of the sine wave if desired. In such a case, it may be useful to include tracking circuitry to determine the peak of the sine wave.

Mathematically, the process for determining the properties of a sine wave from 3 equally spaced measurements can be derived as described below. Let V1, V2 and V3 be 3 consecutive equally spaced voltage measurements on a sine wave signal with a spacing, δ, between V1 and V2 and also between V2 and V3. Further, θ=ωt. The following equations apply:

V₁=Vₚ·sin( [symbol] −δ)

V₂=Vₚ·sin( [symbol] )

V₃=Vₚ·sin( [symbol] +δ)

The following ratios are formed for simplicity:

$${R}_{1} = \frac{{V}_{1}}{{V}_{p}} = sin ( ϑ - δ )$$

$${R}_{2} = \frac{{V}_{2}}{{V}_{p}} = sin ( ϑ )$$

$${R}_{13} = \frac{{V}_{3}}{{V}_{p}} = sin ( ϑ + δ )$$

After further manipulation:

$${R}_{3} - {R}_{1} = 2 \cdot cos ( ϑ ) \cdot sin ( δ )$$

$${R}_{3} + {R}_{1} = 2 \cdot sin ( ϑ ) \cdot cos ( δ )$$

$${( {R}_{3} - {R}_{1} )}^{2} = 4 \cdot {cos}^{2} ( ϑ ) \cdot {sin}^{2} ( δ )$$

$${( {R}_{3} + {R}_{1} )}^{2} = 4 \cdot {sin}^{2} ( ϑ ) \cdot {cos}^{2} ( δ ) = 4 \cdot {R}_{2}^{2} \cdot {cos}^{2} ( δ )$$

$${cos}^{2} ( δ ) = \frac{{( {R}_{3} + {R}_{1} )}^{2}}{4 \cdot {R}_{2}^{2}} \cdot {sin}^{2} ( δ ) = 1 - \frac{{( {R}_{3} + {R}_{1} )}^{2}}{4 \cdot {R}_{2}^{2}}$$

Inserting these results into (R3−R1)² and multiplying through by Vₚ² yields the following:

$${( {R}_{3} - {R}_{1} )}^{2} = 4 \cdot ( 1 - {R}_{2}^{2} ) \cdot [ 1 - \frac{{( {R}_{3} + {R}_{1} )}^{2}}{4 \cdot {R}_{2}^{2}} ]$$

$${( {R}_{3} - {R}_{1} )}^{2} = 4 \cdot [ 1 - \frac{{( {R}_{3} + {R}_{1} )}^{2}}{4 \cdot {R}_{2}^{2}} - {R}_{2}^{2} + \frac{{( {R}_{3} + {R}_{1} )}^{2}}{4} ]$$

$${( {V}_{3} - {V}_{1} )}^{2} = [ 4 - \frac{{( {V}_{3} + {V}_{1} )}^{2}}{{V}_{2}^{2}} ] \cdot {V}_{p}^{2} - 4 \cdot {V}_{2}^{2} + {( {V}_{3} + {V}_{1} )}^{2}$$

Finally, solving for Vₚ²:

$${V}_{p}^{2} = {V}_{2}^{2} \cdot \frac{{V}_{2}^{2} - {V}_{1} \cdot {V}_{3}}{{V}_{2}^{2} - \frac{1}{4} \cdot {( {V}_{3} + {V}_{1} )}^{2}} ; {sin}^{2} ( θ ) = \frac{{V}_{2}^{2}}{{V}_{p}^{2}} ;$$

Therefore, Vₚ² can be exactly determined from 3 equally spaced measurements. The computation requires 4 multiply operations and 1 divide operation. In many situations with amplitude comparisons to a reference value, such as in trip point sensors, the determination of Vₚ or Vₚ² is immaterial. When the amplitude is important, a square root algorithm can be added to determine Vₚ. Processors with a hardware multiply instruction can handle this algorithm very well. Fast square root algorithms are also applicable.

In making the 3 equally spaced voltage measurements, it would be useful to choose θ so that V₂ is not near the zero-crossing of the sine wave. When V₂ is measured near the zero crossing, the result can be indeterminate with a noisy result for Vₚ.

An alternative approximation can be employed when the 3 samples are taken in the vicinity of, but not precisely at, the peak of the sine wave. It is computationally simpler than the exact method and also does not require precise spacing of the sampling pulses on the peak and is based upon the quadratic dependence on θ of sin θ near 0=π/2. Large deviations from θ=π/2 will introduce errors.

$${V}_{p} = {V}_{2} + \frac{1}{8} \cdot \frac{{( {V}_{1} - {V}_{3} )}^{2}}{( 2 {V}_{2} - {V}_{1} - {V}_{3} )}$$

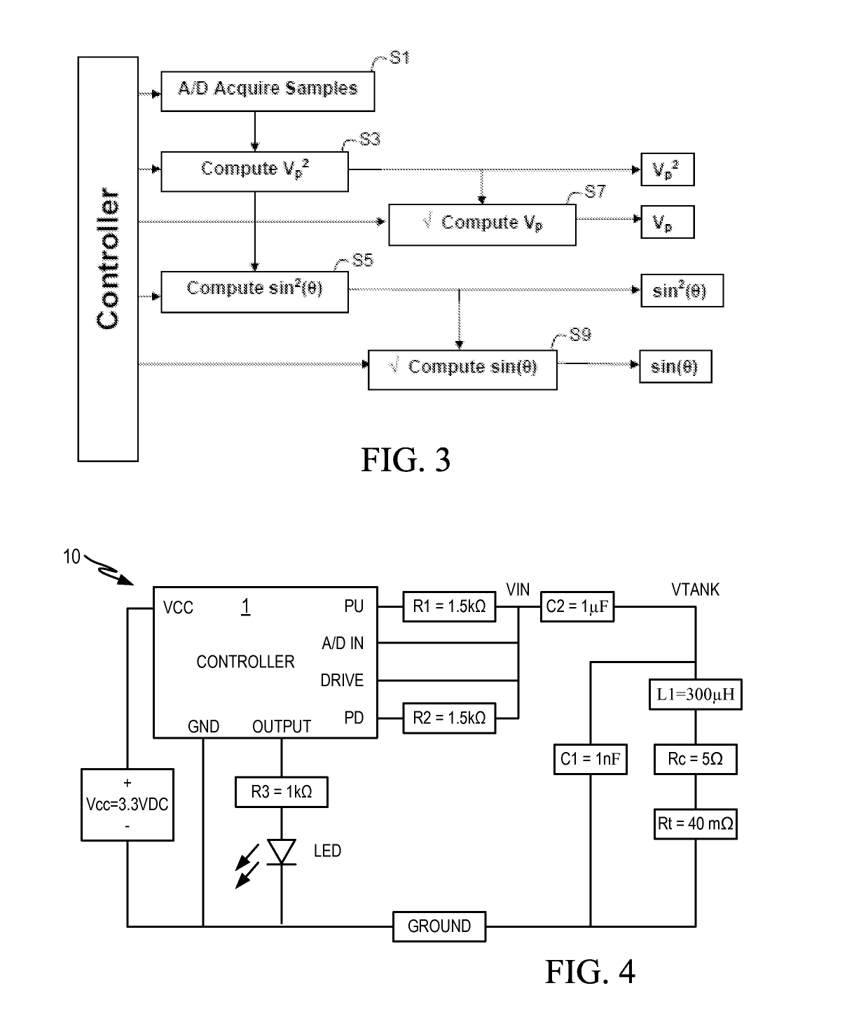

The methodology discussed above avoids the need to sample the sine wave exactly at the peak of the sine wave, and is shown schematically in FIG. 3. The A/D converter 7 acquires the 3 equally spaced voltage measurements V₁, V₂ and V₃ (step S1). Using the voltage measurements, the controller calculates Vₚ² according to:

$${V}_{p}^{2} = {V}_{2}^{2} \cdot \frac{{V}_{2}^{2} - {V}_{1} \cdot {V}_{3}}{{V}_{2}^{2} - \frac{1}{4} \cdot {( {V}_{3} + {V}_{1} )}^{2}} \qquad ( step S3 )$$

If desired, the controller can calculate Vₚ from Vₚ² by taking the square root of Vₚ² (step S5).

The controller 1 calculates sin²(θ) from Vₚ² according to:

$${sin}^{2} ( θ ) = \frac{{V}_{2}^{2}}{{V}_{p}^{2}} \qquad ( step S7 )$$

If desired, the controller can calculate sin(θ) from sin 2(θ) by taking the square root of sin 2(θ) (step S9).

Turning to FIG. 2, an example of an input signal source 9 is a proximity sensor (such as an eddy-current or inductive proximity sensor). Conventional proximity sensors provide a sine wave signal to a control circuit that includes a custom-designed ASIC for analyzing the sine wave signal. Using the methods discussed above, instead of employing an ASIC, the sine wave from a proximity sensor can be analyzed using an off-the-shelf microprocessor having an on-board A/D converter, but programmed with computer-executable instructions stored in the RAM 3, ROM 5, other computer-readable memory accessible to the controller 1, or any combination thereof, specifically to process the sine wave as described herein. This may result in a significant costs savings over conventional proximity sensors by reducing hardware complexity and system resources required to perform the A/D conversion.

The off-the-shelf microcontroller can be programmed to perform the calculations discussed above to determine the amplitude and phase of the sine wave signal transmitted by the proximity sensor in response to being approached by an object, optionally based on samples obtained independent of the phase of the sampled signal provided by a PLL or other tracking component. In other words, the microcontroller can be configured to simply take the samples, with the pins (represented in the drawings as the intersection of a signal line with the perimeter of the controller 1) of the controller 1 operating as sensors for sensing the appropriate signal (e.g., an “on” or an “off” voltage at the pins) at regularly-scheduled, equally-spaced times regardless of the phase and/or frequency of the sine wave. Alternate embodiments can employ separate, stand-alone sensor component operatively coupled to the A/D converter to sense the quality of the sine wave. The microcontroller 1 can provide information about the amplitude and phase of the proximity sensor signal to another device, such as a programmable logic controller (PLC). For example, the microcontroller can also directly control a device, such as a switch (e.g., relay or transistor) or an actuator based on the amplitude and determined phase of the sine wave signal.

In general, the field of application for the devices and methodologies discussed above would be in any receiver (e.g., radio, microwave, optical fiber, etc.) in which digital processing of the information is desired. Whatever format the information is transmitted in (e.g., radio, microwave, optical fiber), it is down-converted to the so-called baseband whereupon the information (video, audio, etc) is extracted.

Additional example applications for the devices and methodologies discussed above include accelerometer applications, AC strain gauge amplifiers, cell phones, resolvers, power line measurements, capacitive sensors, phase detectors, linear variable differential transducer (LVDT) linear position sensors, and any other device that converts a sine wave into a digital format using an A/D converter before interpreting the digital results to produce a desired result.

The general methodologies and apparatus discussed above can be adapted specifically for processing a damped sine wave to determine the same, or similar properties of such a signal, optionally independent of any tracking or synchronization circuitry or data such as that provided by a PLL. In the general case of a damped sine wave the resulting decaying voltage, Vₙ, with an initial voltage amplitude, Vₚ, is given by:

Vₙ=Vₚ·e^{-nατ}·cos(nωτ)

where α is the decay constant, w is the frequency, and τ is the known period of the sampling clock.

$$let x = {e}^{- α τ} ; \frac{{V}_{n}^{2}}{{V}_{p}^{2}} \cdot {x}^{- 2 n} = {cos}^{2} ( n ω τ ) \qquad ( 2 )$$

Then, after forming Vn+1 and Vn−1, expanding the cos( ) terms and adding and then performing further simplification the following expression is obtained:

$${[ {V}_{n - 1} x + \frac{{V}_{n + 1}}{x} ]}^{2} = 4 \cdot {V}_{n}^{2} \cdot {cos}^{2} ( ω τ ) \qquad ( 3 )$$

After performing a summation over the number of samples, N, and solving for cos²(ωt), the result is:

$${cos}^{2} ( ω τ ) = \frac{{\sum }_{n = 1}^{N} {[ {V}_{n - 1} x - \frac{{V}_{n + 1}}{x} ]}^{2}}{4 \cdot {\sum }_{n = 1}^{N} {V}_{n}^{2}} \qquad ( 4 )$$

A similar expression is derived for sin²(ωt) by taking the difference of Vₙ₋₁ and Vₙ₊₁ and solving, yielding:

$${sin}^{2} ( ω τ ) = \frac{{\sum }_{n = 1}^{N} {[ {V}_{n - 1} x - \frac{{V}_{n + 1}}{x} ]}^{2}}{4 \cdot {V}_{p}^{2} \cdot {\sum }_{n = 1}^{N} {x}^{2 n} - 4 \cdot {\sum }_{n = 1}^{N} {V}_{n}^{2}} \qquad ( 5 )$$

Using the relationship sin²( )+cos²( )=1 to eliminate wt in equations (4) and (5) results in:

$$\frac{{\sum }_{n = 1}^{N} {[ {V}_{n - 1} x + \frac{{V}_{n + 1}}{x} ]}^{2}}{4 \cdot {\sum }_{n = 1}^{N} {V}_{i}^{2}} + \frac{{\sum }_{i = 1}^{n} {[ {V}_{i - 1} x - \frac{{V}_{i + 1}}{x} ]}^{2}}{4 \cdot {V}_{p}^{2} \cdot {\sum }_{n = 1}^{N} {x}^{2 n} - 4 \cdot {\sum }_{n = 1}^{N} {V}_{n}^{2}} - 1 = 0 \qquad ( 6 )$$

Finally, the following expressions are used:

$${\sum }_{n = 1}^{N} {x}^{2 n} = \frac{{x}^{2} ( {x}^{2 N} - 1 )}{( {x}^{2} - 1 )} and from ( 2 ) with n = 1 \\ \frac{{V}_{l}^{2}}{{V}_{p}^{2}} = {x}^{- 2 n} {cos}^{2} ( ω τ ) \\ {V}_{p}^{2} = \frac{{x}^{2} {V}_{l}^{2}}{{cos}^{2} ( ω τ )} \qquad ( 7 )$$

to obtain, after rearrangement to simplify the expression:

$$F ( x ) = \frac{{\sum }_{n = 1}^{N} {[ {V}_{n - 1} x + \frac{{V}_{n + 1}}{x} ]}^{2}}{4 \cdot {\sum }_{n = 1}^{N} {V}_{n}^{2}} + \frac{( 1 - {x}^{2} ) \cdot {\sum }_{n = 1}^{N} {[ {V}_{n - 1} x - \frac{{V}_{n + 1}}{x} ]}^{2}}{4 \cdot {V}_{l}^{2} \cdot \frac{{x}^{4}}{\frac{{\sum }_{n = 1}^{N} {[ {V}_{n - 1} x + \frac{{V}_{n + 1}}{x} ]}^{2}}{4 \cdot {\sum }_{n = 1}^{N} {V}_{n}^{2}}} ( 1 - {x}^{2 n} ) - 4 \cdot ( 1 - {x}^{2} ) {\sum }_{n = 1}^{N} {V}_{n}^{2} } - 1 \qquad ( 8 )$$

Finding a negative real root, x₀, of F(x)=0 will give the desired decay constant αt=−1n(x₀), and wt can then be found by inserting x₀ back into equation (4). The following examples illustrate the application of the above method and apparatus.

Free Induction Decay (FID)

A schematic of an inductive proximity sensor 10 employing FID is shown in FIG. 4. According to the present embodiment, the controller 1 provides a voltage VCC/2 to C2 by activating the output on pins PU and PD while the output on pin DRIVE is off. To initiate the FID, PU and PD are turned off and capacitor C1 is charged to a voltage VCC by the output on the pin DRIVE. When the output on DRIVE is turned off the FID begins and the voltage VIN is sampled at pin ADIN of the controller 1. After the desired decay time, the output on pins PU and PD are again turned on, quenching the oscillation on VTANK and restoring VIN to VCC/2. During this time computations are performed by the controller 1 to extract ω and τ using the algorithms described above with reference to equations (1)-(8). Following this, the output on pin DRIVE of the microcontroller 1 is turned on and the cycle repeats.

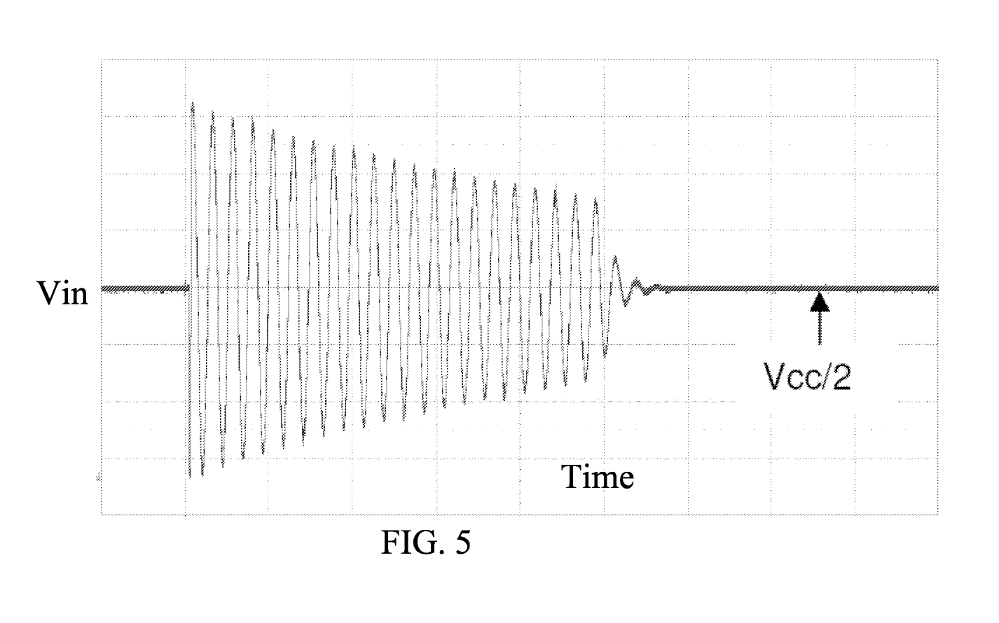

As a metal target approaches the inductor, L1 in FIG. 4, the resistance due to eddy currents in the target, Rt, is added to the coil resistance, Rc. This affects the damping constant according to the expression α=(Rc+Rt)/2 L. Calculating the damping constant α can provide a high resolution measurement of the target resistance, which is inversely proportional to the separation of the metal target to the sensor coil L1. FIG. 5 shows a simulated damped sine wave produced by an inductive proximity sensor 10 such as that shown in FIG. 4.

For this simulation n=24 samples, Rc=5.00Ω, Rt=40 mΩ, L=269.59 μH, C=2.2 nF and:

V(n)=V₀e^{-nατ}cos [ω(nτ+T_{d})]

with V₀=1968, τ=6.9091 μsec

and T_{d}=4.001/μsec (9)

The solution, x₀, is found with a root function to be: x₀=0.937458 and the calculated value, Rc+Rt, is given by:

$$Rc + Rt = - 2 \frac{L}{τ} ln ( 0.937458 ) = 5.040000000 Ω \qquad ( 10 )$$

This result is in agreement with the specified value of the sum Rc+Rt defined above.

F(x) can also be calculated by an iterative process according to computer-executable instructions executed by the controller 1 after the samples are taken by incrementing the variable x until the sign of F(x) changes. A feedback loop established by the computer-executable instructions enables the current value of x to track changes in the target distance. The value of x is then compared to a reference value to determine if a set point has been reached. According to an alternate calculation, the x value can provide an output inversely proportional to distance. But regardless of the specific methodology used to solve the algorithms above, the values sampled independently of the phase of the local oscillator provided to the controller 1 minimizes the computational resources of the controller 1 consumed by such calculations, thereby improving the efficiency of the controller 1, and allowing the controller 1 to determine the desired result faster and possibly reserving computational resources that can be utilized for other tasks.

Proton Precession Magnetometer

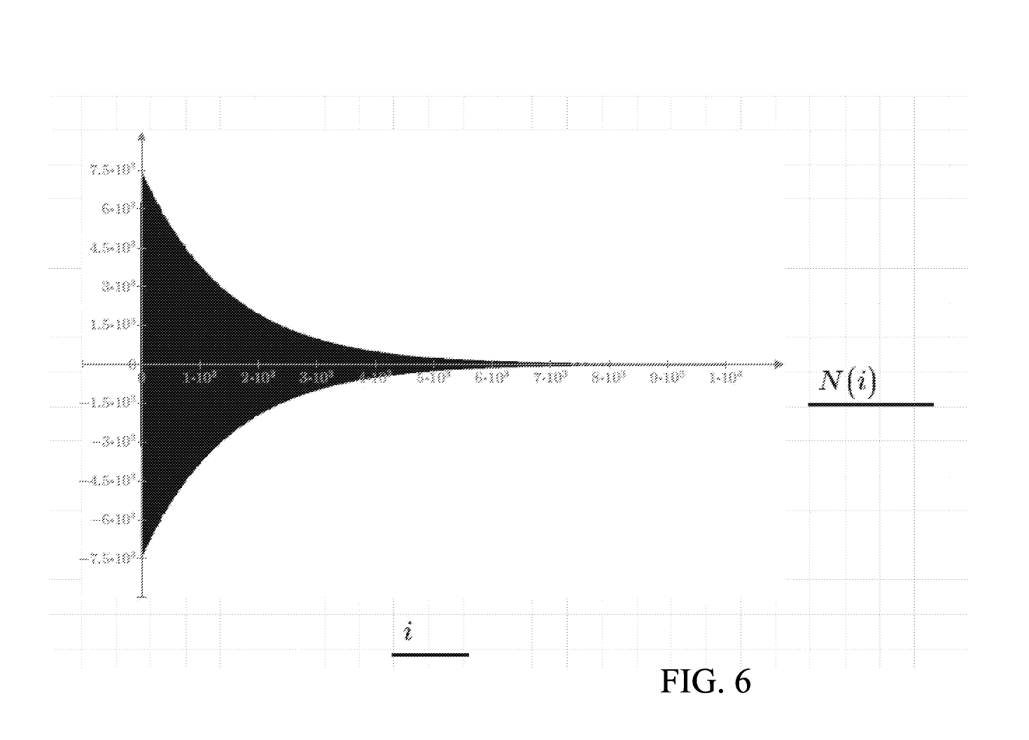

Equation (8) derived above can also be applied to the FID signal, shown in FIG. 6, from an earth's magnetic field NMR magnetometer. This FID signal consists of ˜15,000 samples taken at a sampling rate of 10,000 samples per second. The parameter of concern is the frequency of the FID, typically 2.3 kHz in the earth's magnetic field. The frequency is equal to the Larmor constant times the magnetic field and is a result of the nuclear magnetic resonance of the hydrogen nucleus in an aqueous sample fluid. While the NMR pickup coil surrounding the aqueous sample fluid is resonated as above with a capacitor to improve the signal to noise ratio, the actual resonance observed is very narrow and contained within the broad LC resonance of the coil and capacitor. This is the energy absorbed by the atomic nuclear magnetic moment precession in the earth's magnetic field. This FID is characterized by a very long decay time compared to the period of oscillation and results in a value of x very close to unity. In this case the cos²(ωt) term in equation (4) above yields a close approximation to the frequency by setting x=1, resulting in the following expression:

$${cos}^{2} ( ω τ ) = \frac{{\sum }_{n = 1}^{N} {[ {V}_{n - 1} + {V}_{n + 1} ]}^{2}}{4 \cdot {\sum }_{n = 1}^{N} {V}_{n}^{2}} \qquad ( 11 )$$

To compare the expected 2.3 kHz frequency of the FID in the earth's magnetic field to the frequency of an NMR test FID based on the algorithms herein, a simulation was performed using the following:

Vₙ=Vₚ·e^{-nατ}·cos(2πnfτ) (12)

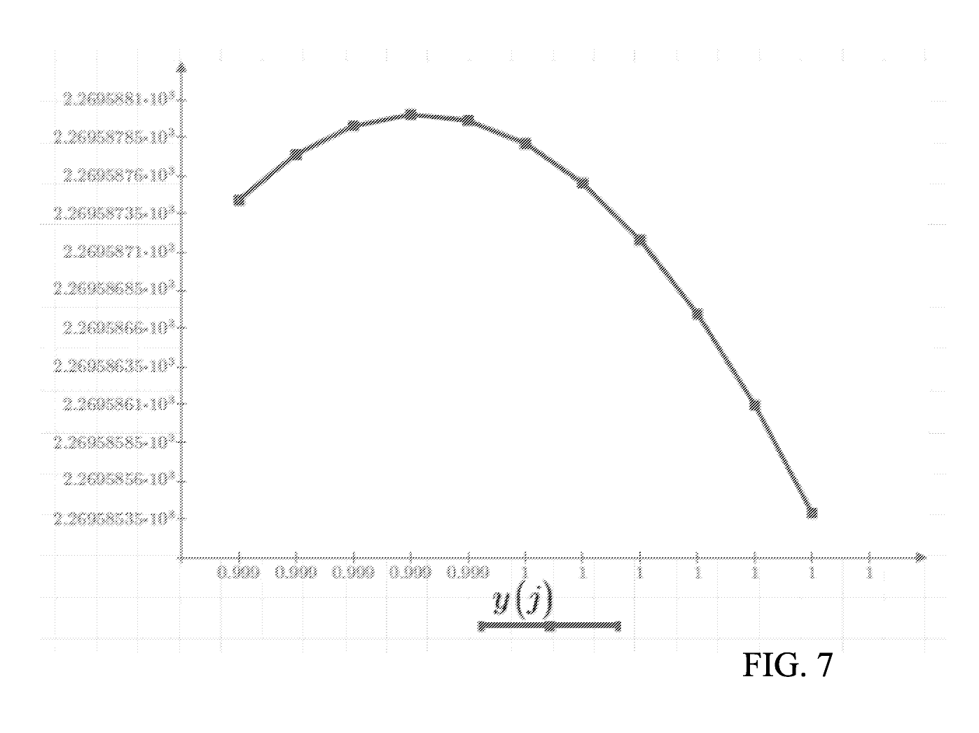

which simply replaces the angular frequency ω in equation (1) with its equivalent 2πf, utilizing the values: Vₚ=7500, f=2269.588 Hz, α=6.7 s⁻¹ and t=100 s. The frequency calculated by the simulation based on equation (11) was 2,269.588 Hz, which is in agreement with the assumed value corresponding to the simulation using equation (12). In fact, the variation of simulations using equation (4) from values determined by coordinating phases of the sampled signal and the sample clock as a function of x was determined to be acceptably-small in most situations, as illustrated in FIG. 7. The acceptable limit of such variation can be established based on the accuracy requirements of the particular application in which the present technology is used.

Zero Decay Constant (Demodulation)

Another embodiment of the present apparatus and method involves a situation in which the decay constant is zero, which corresponds to an undamped sine wave. According to the present embodiment, r=α=0, and x=1, reducing equation (6) to:

$${V}_{p}^{2} = \frac{1}{N} \cdot [ 1 + \frac{{\sum }_{n = 1}^{N} {[ {V}_{i - 1} - {V}_{i + 1} ]}^{2}}{4 \cdot {\sum }_{n = 1}^{N} {V}_{i}^{2} - {\sum }_{n = 1}^{N} {[ {V}_{i - 1} + {V}_{i + 1} ]}^{2}} ] \cdot {\sum }_{n = 1}^{N} {V}_{i}^{2} \qquad ( 13 )$$

where F(x)=0 now has an explicit solution for Vₚ, namely, the constant amplitude. Equation (13) can then be rewritten as:

$${V}_{p}^{2} = \frac{{\sum }_{n = 1}^{N} {V}_{i}^{2}}{N} \cdot [ \frac{{\sum }_{n = 1}^{N} {V}_{i}^{2} - {\sum }_{n = 1}^{N} [ {V}_{i - 1} {V}_{i + 1} ]}{{\sum }_{n = 1}^{N} {V}_{i}^{2} - \frac{1}{4} {\sum }_{n = 1}^{N} {[ {V}_{i - 1} + {V}_{i + 1} ]}^{2}} ] \qquad ( 14 )$$

The similarity between the form of the result in equation (14) and the form of the result described above with reference to step S3 in FIG. 3 is noteworthy.

It becomes apparent that the results based on equations (11) and (14) are similar to a moving average sum, so that a degree of filtering can be achieved, depending on the choice of N. A large N will provide increased low-pass filtering on Vₚ. Further:

Vₙ=Vₚ·e^{-nατ}·cos(nωτ+φ) (15)

where an arbitrary phase term φ is included since it is encountered in many modulation schemes. The results of equations (11) and (14) are independent of φ. The phase angle can be determined from:

$$cos ( φ ) = \frac{{V}_{0}}{{V}_{p}} or φ = {cos}^{- 1} ( \frac{{V}_{0}}{{V}_{p}} ) \qquad ( 16 )$$

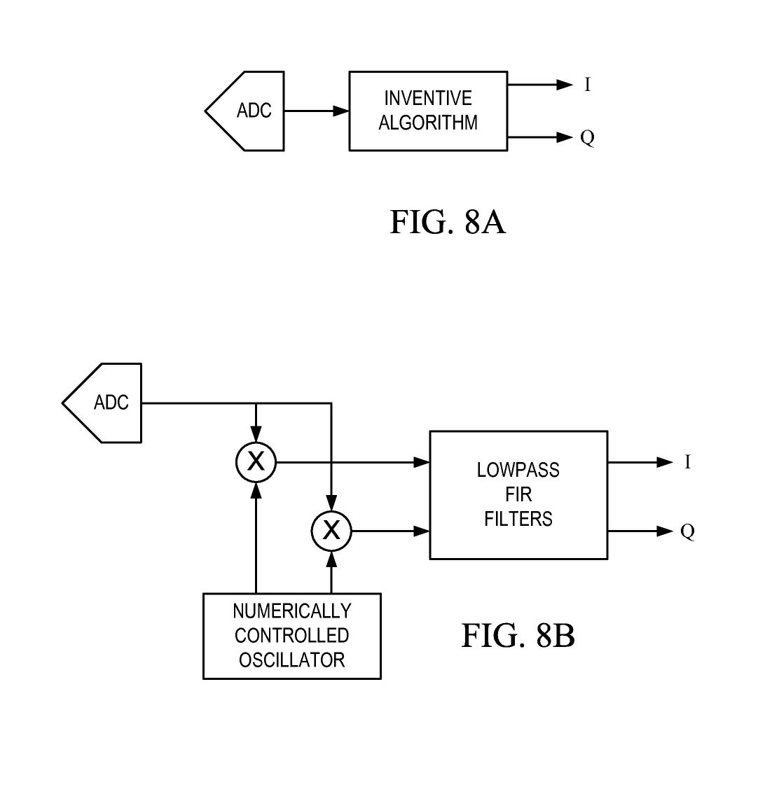

Therefore, the sine wave signal has been demodulated and can be used to generate in-phase (I) and quadrature (Q) signals, typical of many modulation schemes using the amplitude and phase just computed. This avoids the need for dual A/D converters, or, in the case of some single A/D converter circuits, the need for quadrature local oscillators. An illustration of signal paths required of a system employing a conventional numerically controlled oscillator for generating a synchronous representation of a waveform is shown in FIG. 8B for comparison to the signal paths and configuration using the inventive algorithm and apparatus disclosed herein in FIG. 8A, which lacks a numerically controlled oscillator. As shown, the present apparatus and method eliminates the need for the numerically controlled oscillator or other measure to coordinate the rate and/or clock of sampling with the frequency and/or phase of the sine wave being sampled. Since cos(q) is given by equation (16), the I component is determined by multiplying cos(φ) by Vp and the Q component can be found from: V_{Q}=±\sqrt{Vₚ²−V₁²}

where the sign (quadrant) can be determined from the values of V₋₁ and V₊₁.

Exact Solution with Three Equally-Spaced Samples

Another particular embodiment of the present apparatus and method involves determining any or all of the properties of a sine wave mentioned above by performing a A/D conversion using a sampling size of three, equally-spaced samples. For such an embodiment, equation (11) above, with N=1, reduces to:

$${V}_{pn}^{2} = {V}_{n}^{2} \cdot [ 1 + \frac{{[ {V}_{n - 1} - {V}_{n + 1} ]}^{2}}{4 \cdot {V}_{n}^{2} - {[ {V}_{n - 1} + {V}_{n + 1} ]}^{2}} ] \qquad ( 17 )$$

which can be rewritten as:

$${V}_{pn}^{2} = {V}_{n}^{2} \cdot \frac{{V}_{n}^{2} - {V}_{n - 1} {V}_{n + 1}}{{V}_{n}^{2} - \frac{1}{4} {( {V}_{n - 1} + {V}_{n + 1} )}^{2}} \qquad ( 18 )$$

In effect, the formulas ‘fit’ a sine wave to the sampled data, although not in a least squares sense. No restriction has been placed on the sample period, τ. In fact, the amplitude of the assumed sine wave can be calculated with an interval substantially less than a full period of the sine wave being sampled (e.g., an interval of approximately ¼ of the full period, or an interval of approximately ⅓ of the full period, or an interval that is less than half of the full period, etc.).

Useful Approximations

Under certain circumstances it may be reasonable to use approximations to further simplify the methods and apparatus described above for the embodiment utilizing three, equally-spaced samples. For example, it may be convenient to express equation (18) as follows:

$${V}_{pn}^{2} = {V}_{n}^{2} \cdot [ 1 + \frac{{[ {V}_{n - 1} - {V}_{n + 1} ]}^{2}}{4 \cdot {V}_{n}^{2} - {[ {V}_{n - 1} - {V}_{n + 1} ]}^{2} - 2 {V}_{n - 1} {V}_{n + 1}} ] \qquad ( 19 )$$

If all three samples are taken near the peak amplitude, then:

[Vₙ₋₁−Vₙ₊₁]²<<4·Vₙ² and 2Vₙ₋₁Vₙ₊₁≅2Vₙ²

so that

$${V}_{pi}^{2} ≅ {V}_{i}^{2} \cdot [ 1 + \frac{{[ {V}_{i - 1} - {V}_{i + 1} ]}^{2}}{2 \cdot {V}_{i}^{2}} ] \qquad ( 20 )$$

Or, after approximating the square root for a small 2^{nd} term in equation (20),

$${V}_{pn 1} ≅ {V}_{n} + \frac{{[ {V}_{n - 1} - {V}_{n + 1} ]}^{2}}{4 \cdot {V}_{n}} \qquad ( 21 )$$

A better approximation, however, can be obtained by approximating the sine wave with a quadratic expression for samples taken near the peak amplitude of the sine wave. For example:

$${V}_{n} ≅ {V}_{pn} ( 1 - \frac{1}{2} {φ}^{2} ) with {θ}_{n} = φ + \frac{π}{2} \\ {V}_{( n - 1 )} ≅ {V}_{pn} ( 1 - \frac{1}{2} {( φ - τ )}^{2} ) \\ {V}_{( n + 1 )} ≅ {V}_{pn} ( 1 - \frac{1}{2} {( φ + τ )}^{2} ) \qquad ( 22 )$$

In this case θᵢ and τ can be eliminated from equation (22), which can be solved for Vₚᵢ:

$${V}_{pn 2} = {V}_{n} + \frac{1}{8} \frac{{( {V}_{n - 1} - {V}_{n + 1} )}^{2}}{( 2 Vn - {V}_{n - 1} - {V}_{n + 1} )} \qquad ( 23 )$$

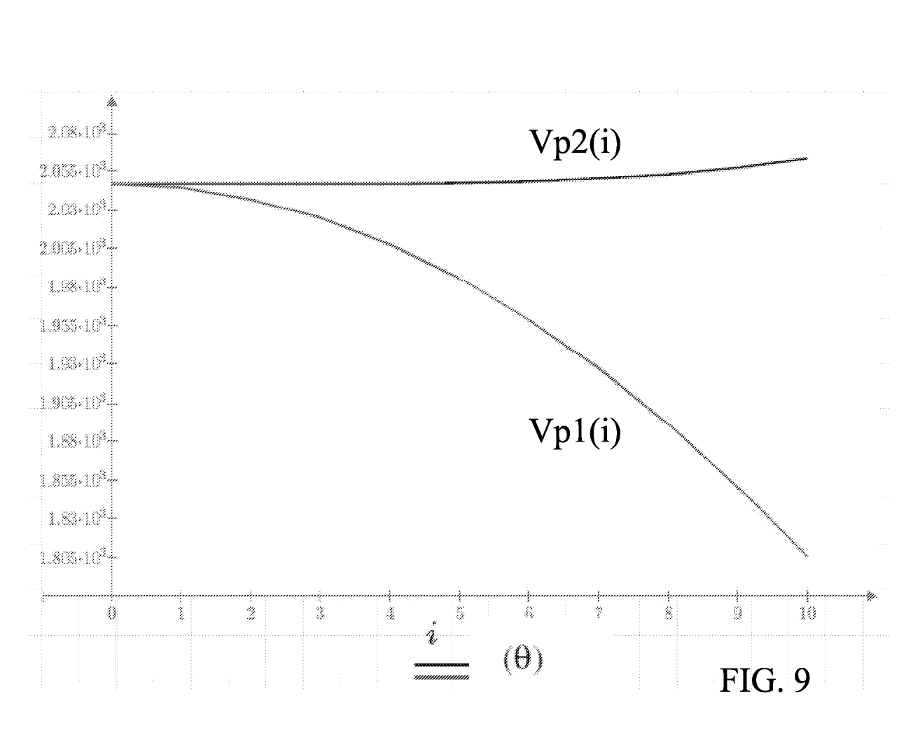

For a 12 bit A/D converter (Vₚ=2047), an accuracy of one least significant bit (“LSB”) is retained for theta as much as 0.3 radians from the peak, which means the determined voltage would still be sufficient to guarantee a change in the output level at that distance from the peak. A comparison of the two approximations is shown in FIG. 9. In FIG. 9, Vp1(i) corresponds to the first approximation discussed above, where all three samples were taken near the peak and the square root of the small 2^{nd} term in equation (20) was approximated, and Vp2(i) corresponds to the second approximation, where a quadratic expression was used to approximate the sine wave for samples near the peak.

An exception to these approximations occurs if the n^{th} sample is at or near a zero crossing of the sine wave. In this case, equation (14) becomes:

$${V}_{pn}^{2} ≅ {V}_{n}^{2} \cdot \frac{{V}_{n - 1} {V}_{n + 1}}{\frac{1}{4} {( {V}_{n - 1} + {V}_{n + 1} )}^{2}} \qquad ( 24 )$$

From equation (24), it is apparent that the calculation for Vₚₙ is no longer accurate if the n^{th} sample is taken at or near the zero crossing as Vₚₙ is approximately 0. An alternative calculation that can give the correct answer involves checking to determine if Vᵢ, is near zero. If so, then samples Vₙ, Vₙ₊₁ and Vₙ₊₂ should all be used for the calculation. For a 12 bit A/D converter (Vp=2047), a 1 LSB accuracy is retained for theta as much as 0.3 radians from the peak of the sine wave. As an alternate solution, a sample size of N=4 samples can be used in (14) instead to avoid the problem, as even if one sample is taken at or near the zero crossing the other three samples can be used as described herein to arrive at the appropriate conclusion.

Illustrative embodiments have been described, hereinabove. It will be apparent to those skilled in the art that the above devices and methods may incorporate changes and modifications without departing from the general scope of this invention. It is intended to include all such modifications and alterations within the scope of the present invention. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. An apparatus for sampling an alternating wave, the apparatus comprising:
a sensor that senses a value of the alternating wave at a plurality of equally-spaced times during a period of the alternating wave, said times being determined independent of at least one of a frequency and a phase of the alternating wave; and
a controller that determines, independently of the at least one of the frequency and the phase of the alternating wave, a desired value of the alternating wave pertinent to a predetermined application of the apparatus based on the value of the alternating wave sensed by the sensor.

2. The apparatus of claim 1, wherein the sensor is adapted to sense the value three times during the period of the alternating wave.

3. The apparatus of claim 1 further comprising an A/D converter that determines, as the desired value, at least one of an amplitude and a decay constant of a sine wave being sampled independently of the at least one of the frequency and the phase of the sine wave.

4. The apparatus of claim 1 further comprising an A/D converter that determines at least one of an amplitude and a decay constant of a cosine wave being sampled independently of the at least one of the frequency and the phase of the cosine wave.

5. The apparatus of claim 1, wherein the controller is programmed to demodulate the alternating signal based on an algorithm having a known decay constant.

6. The apparatus of claim 5, wherein the controller is programmed with a value of zero assigned to the decay constant.

7. The apparatus of claim 1, wherein the controller is programmed to cause the sensor to sense the value at regularly-occurring arbitrary times during the period of the alternating signal.

8. A method of processing an alternating wave, the method comprising:
sampling, with a sensor, a value of the alternating wave at a plurality of equally-spaced times during a period of the alternating wave, said equally-spaced times being determined independently of at least one of a frequency and a phase of the alternating wave;
during an A/D conversion of the alternating signal, and independently of the at least one of the frequency and the phase of the alternating wave, determining a desired value of the alternating wave pertinent to a predetermined application of the apparatus based on the value of the alternating wave sensed by the sensor at the equally-spaced times.

9. The method of claim 8, wherein said value is sensed at arbitrary times relative to the alternating signal.

10. The method of claim 8, wherein said sampling comprises:
driving, with the controller, a decaying voltage signal having a known decay constant; and
sensing a voltage value of the decaying voltage as the value sensed at the equally-spaced times; and
determining a frequency component of the alternating wave and a period of a sampling clock based on the voltage value sensed at each of the equally-spaced times.

11. The method of claim 10, wherein said sampling is performed without tracking data used to coordinate the at least one of the frequency and the phase of the alternating wave with at least one of a sampling frequency and a sampling phase of the sampling clock.

12. The method of claim 8, wherein the A/D conversion comprises determining, as the desired value, at least one of an amplitude and a decay constant of a sine wave being sampled independently of the at least one of the frequency and the phase of a sine wave as the alternating signal.

13. The method of claim 8, wherein the A/D conversion comprises determining at least one of an amplitude and a decay constant of a cosine wave being sampled independently of the at least one of the frequency and the phase of a cosine wave as the alternating signal.

14. The method of claim 8 further comprising demodulating, with the controller, the alternating signal based on an algorithm having a known decay constant.
